(19) United States
(12) Patent Application Publication
(10) Pub. No.: US 2004/0187789 A1
(43) Pub. Date: Sep. 30, 2004

(54) WAFER HOLDER FOR SEMICONDUCTOR MANUFACTURING DEVICE AND SEMICONDUCTOR MANUFACTURING DEVICE IN WHICH IT IS INSTALLED

(75) Inventors: Masuhiro Natsuhara, Itami-shi (JP); Hirohiko Nakata, Itami-shi (JP); Manabu Hashikura, Itami-shi (JP)

Correspondence Address: JUDGE PATENT FIRM, RIVIERE SHUKUGAWA 3RD FL., 3-1 WAKAMATSU-CHO, NISHINOMIYA-SHI, HYOGO, 662-0035, JP

(73) Assignee: SUMITOMO ELECTRIC INDUSTIES, LTD., Osaka-shi (JP)

(21) Appl. No.: 10/604,133

(22) Filed: Jun. 27, 2003

(30) Foreign Application Priority Data
Mar. 31, 2003 (JP) JP-2003-064279

(51) Int. Cl. C23C 16/00; C23F 1/00

(52) U.S. Cl. 118/728; 156/345.51

(57) ABSTRACT

Wafer holder for semiconductor manufacturing and semiconductor manufacturing device in which the holder is installed, the wafer holder having a wafer-carrying surface, wherein the isothermal rating of its wafer-carrying surface is enhanced. In the wafer holder having a wafer-carrying surface, a shaft that supports the wafer holder is joined to the wafer holder; by making the in-shaft heat capacity of electrodes for supplying power to an electrical circuit formed either on a surface other than the wafer-carrying surface of the wafer holder, or else inside it, 10% or less of the heat capacity of the region of wafer holder that corresponds to the shaft, the temperature distribution in the wafer surface can be brought within an isothermal rating of Â±1.0%. The electrical circuit formed in the wafer holder is preferably at least a resistive heating element.

### BACKGROUND OF INVENTION

1. Field of the Invention

The present invention relates to wafer holders employed in semiconductor manufacturing devices such as plasma-assisted CVD, low-pressure CVD, metal CVD, dielectric-film CVD, ion-implantation, etching, Low-K film heat treatment, and degassing heat treatment devices, and furthermore to process chambers and semiconductor manufacturing devices in which the wafer holders are installed.

2. Description of the Background Art

Conventionally, in semiconductor manufacturing procedures various processes such as film deposition processes and etching processes are carried out on semiconductor substrates that are the processed objects. Ceramic susceptors that retain such semiconductor substrates in order to heat them are used in the processing devices in which the processes on the semiconductor substrates are carried out.

Japanese Pat. App. Pub. No. H04-78138 for example discloses a conventional ceramic susceptor of this sort. The ceramic susceptor includes: a heater part made of ceramic, into which a resistive heating element is embedded and that is provided with a wafer-heating surface, arranged within a chamber; a columnar support part that is provided on a surface apart from the wafer-heating surface of the heating section and that forms a gastight seal between it and the chamber; and electrodes connected to the resistive heating element and leading outside the chamber so as essentially not to be exposed to the chamber interior space.

Although this invention serves to remedy the contamination and poor thermal efficiency that had been seen with heaters made of metal—heaters prior to the invention—it does not touch upon temperature distribution in semiconductor substrates being processed. Nonetheless, semiconductor-substrate temperature distribution is crucial in that it proves to be intimately related to yield in the situations where the aforementioned various processes are carried out. Given the importance of temperature distribution, Japanese Pat. App. Pub. No. 2001-118664, for example, discloses a ceramic susceptor capable of equalizing the temperature of the ceramic substrate. In terms of this invention, it is tolerable in practice that the temperature differential between the highest and lowest temperatures in the ceramic substrate surface be within in several %.

Scaling-up of semiconductor substrates has been moving forward in recent years, however. For example, with silicon (Si) wafers, a transition from 8-inch to 12-inch is in progress. Consequent on this impressive diametric enlarging of the semiconductor substrate, that the temperature distribution in the heating surface (retaining surface) of semiconductor substrates on ceramic susceptors be within Â±1.0% has become a necessity; that it be within Â±0.5% has, moreover, become an expectation.

### SUMMARY OF INVENTION

The present invention has been brought about to address the foregoing issues. In particular, an object of the present invention is to realize for semiconductor manufacturing devices a wafer holder with enhanced isothermal properties in its wafer-retaining surface, and a semiconductor manufacturing device in which it is installed.

The present invention was arrived at by discovering that in the semiconductor-manufacturing-device wafer holder set out in Japanese Pat. App. Pub. No. H04-78138, temperature distribution in the wafer-carrying surface of the wafer holder becomes non-uniform because heat generated in the heater circuit is transmitted to the electrodes, and as a consequence the temperature of the wafer-carrying surface directly over the electrodes drops relative to the rest of the surface.

Namely, in the present invention, in a wafer holder having a wafer-carrying surface, the in-shaft heat capacity of electrodes for supplying power to an electrical circuit formed either on a surface other than the wafer-carrying surface of the wafer holder, or else inside it, is 10% or less of the heat capacity of the region of wafer holder that corresponds to the shaft. More preferably, it is 5% or less. The electrical circuit formed in the wafer holder is preferably at least a resistive heating element.

In a semiconductor manufacturing device in which a wafer holder as in the foregoing is installed, the temperature of a wafer that is being processed proves to be more uniform than what has been making for better-yield manufacturing of semiconductors.

From the following detailed description in conjunction with the accompanying drawings, the foregoing and other objects, features, aspects and advantages of the present invention will become readily apparent to those skilled in the art.

### BRIEF DESCRIPTION OF DRAWINGS

FIG. 1 illustrates one example of the sectional structure of a wafer holder according to the present invention; and

FIG. 2 is a plan view along the undersurface of the wafer holder of FIG. 1.

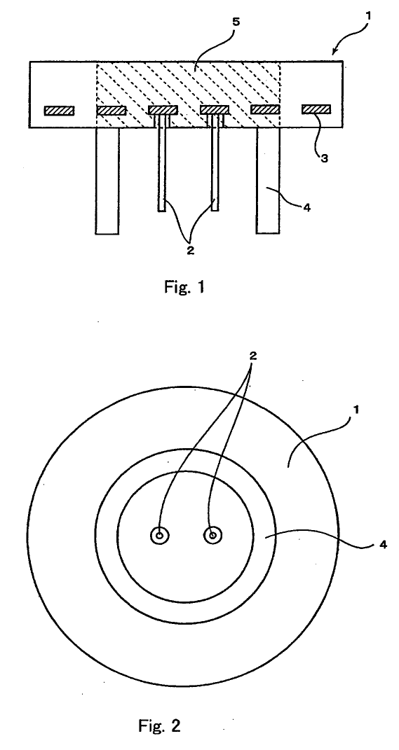

### DETAILED DESCRIPTION

The present inventors discovered that in order to get the temperature distribution in the wafer-retaining surface to be within Â±1.0%, the heat capacity of electrodes 2 where they are within a shaft 4, for supplying power to electric circuits 3 formed in a wafer holder 1, should be 10% or less of the heat capacity of a region 5 of the wafer holder that corresponds to inside the outer periphery of the shaft.

Herein, the electric circuits can be resistive heat-generating (heater) circuits or RF electrode circuits for generating plasma, or else can be electrostatic-chuck circuits for electrostatically retaining wafers. Such electric circuits preferably are equipped with at least a resistive heat-generating circuit, but at the same time may be equipped with other circuits. These electrodes 2 for supplying power to the circuits are, as shown in FIG. 2, disposed within the shaft 4.

A wafer undergoes predetermined processes with the wafer holder heating the wafer by means of a resistive heating element 3 formed either in the interior of the wafer holder, or else on a surface other than its wafer-carrying face. But if the electrode in-shaft heat capacity exceeds 10% of the heat capacity of the portion of the wafer holder that corresponds to the shaft, the heat generated by the resistive heating element will readily escape through the electrodes, such that temperature distribution in the wafer-carrying surface is liable to be non-uniform. The fact the temperature of the wafer being carried will drop sporadically if the temperature of the wafer-carrying face drops sporadically will for example create fluctuations in the thickness and properties of films formed when a film-forming process is conducted on the wafer. And in etching processes, for example, fluctuations in etching speed will be produced.

This is why as slight as possible a temperature distribution in the wafer-carrying surface—currently, an isothermal rating of within Â1.0%, with expectations for an isothermal rating of within Â±0.5% likely—is being sought. It was discovered that in order to gain an isothermal rating along these lines, the electrode in-shaft heat capacity should be 10% or less of the heat capacity of the portion of the wafer holder that corresponds to the shaft.

The heat generated by the ceramic heater not only heats the wafer-carrying face but also diffuses to surfaces other than the wafer-carrying face, and to electrodes connected to the ceramic heater. Under the circumstances, if a large amount of heat is transmitted to the electrodes inside the shaft, the temperature of the wafer-carrying face directly above the electrodes will drop. Moreover, inasmuch as the interior of the shaft is isolated from the atmosphere inside the chamber and is normally at normal pressure, heat transfer to the shaft interior by convection is probable. Heat transfer to the electrodes within the shaft consequently has a significant influence on temperature drop in the wafer-carrying face.

The amount of heat transfer to the electrodes within the shaft grows greater with a greater electrode number or a larger electrode size. Specifically, the larger the electrode in-shaft heat capacity, the greater the amount of heat transfer to the electrodes is, and the larger the temperature distribution in the wafer-carrying face is. If the temperature distribution in the wafer-carrying face grows large, the temperature distribution in the surface of the wafer being carried also grows large. If the temperature distribution in the wafer surface is to be brought within an isothermal rating of Â±1.0%, the in-shaft heat capacity of the electrodes should be 10% or less of the heat capacity of the region of the wafer holder that corresponds to the shaft. Moreover, 5% or less is preferable because the temperature distribution in the wafer-carrying face accomplishes an isothermal rating of Â±0.5% or less.

It should be understood that “in-shaft heat capacity of the electrodes” is the heat capacity of the entire electrodes when the electrodes are shorter than the shaft, but is the heat capacity of the electrodes up to the end part of the shaft if the electrodes are longer than the shaft. It should also be understood that when the electrodes are formed in a plurality, the heat capacity is the total of the plurality of electrodes.

Insofar as the substances for a wafer holder according to the present invention are insulative ceramics, they are not particularly restricted, but aluminum nitride (AlN) is preferable for its high thermal conductivity and superior corrosion resistance. In the following, a method according to the present invention of manufacturing a wafer holder in a AlN instance will be described in detail.

An AlN raw-material powder whose specific surface area is 2.0 to 5.0 m²/g is preferable. The sinterability of the aluminum nitride declines if the specific surface area is less than 2.0 m²/g. Handling proves to be a problem if on the other hand the specific surface area is over 5.0 m²/g, because the powder coherence becomes extremely strong. Furthermore, the quantity of oxygen contained in the raw-material powder is preferably 2 wt. % or less. In sintered form, its thermal conductivity deteriorates if the oxygen quantity is in excess of 2 wt. %. is also preferable that the amount of metal impurities contained in the raw-material powder other than aluminum be 2000 ppm or less. The thermal conductivity of the powder in sintered form deteriorates if the amount of metal impurities exceeds this range. In particular, the content respectively of Group IV elements such as Si, and elements of the iron family, such as Fe, which have a serious worsening effect on the thermal conductivity of the sinter, is advisably 500 ppm or less.

Because AlN is not a readily sinterable material, adding a sintering promoter to the AlN raw-material powder is advisable. The sintering promoter added preferably is a rare-earth element compound. Since rare-earth element compounds react with aluminum oxides or aluminum oxynitrides present on the surface of the particles of the aluminum nitride powder, acting to promote densification of the aluminum nitride and to eliminate oxygen being a causative factor that worsens the thermal conductivity of an aluminum nitride sinter, they enable the thermal conductivity of aluminum sinters to be improved.

Yttrium compounds, whose oxygen-eliminating action is particularly pronounced, are preferable rare-earth element compounds. The amount added is preferably 0.01 to 5 wt. %. If less than 0.01 wt. %, producing ultrafine sinters is problematic, along with which the thermal conductivity of the sinters deteriorates. Added amounts in excess of 5 wt. % on the other hand lead to sintering promoter being present at the grain boundaries in an aluminum nitride sinter, and consequently, if the aluminum nitride sinter is employed under a corrosive atmosphere, the sintering promoter present along the grain boundaries gets etched, becoming a source of loosened grains and particles. More preferably the amount of sintering promoter added is 1 wt. % or less. If less than 1 wt. % sintering promoter will no longer be present even at the grain boundary triple points, which improves the corrosion resistance.

To characterize the rare-earth compounds further: oxides, nitrides, fluorides, and stearic oxide compounds may be employed. Among these oxides, being inexpensive and readily obtainable, are preferable. By the same token, stearic oxide compounds are especially suitable since they have a high affinity for organic solvents, and if the aluminum nitride raw-material powder, sintering promoter, etc. are to be mixed together in an organic solvent, the fact that the sintering promoter is a stearic oxide compound will heighten the miscibility.

Next, the aluminum nitride raw-material powder, sintering promoter as a powder, a predetermined volume of solvent, a binder, and further, a dispersing agent or a coalescing agent added as needed, are mixed together. Possible mixing techniques include ball-mill mixing and mixing by ultrasound. Mixing can thus produce a raw material slurry.

The obtained slurry can be molded, and by sintering the molded product, an aluminum nitride sinter can be produced. Co-firing and post-metallization are two possible methods as a way of doing this.

Metallization will be described first. Granules are prepared from the slurry by means of a technique such as spray-drying. The granules are inserted into a predetermined mold and subject to press-molding. The pressing pressure therein desirably is 0.1 t/cm² or more. With pressure less than 0.1 t/cm², in most cases sufficient strength in the molded mass cannot be produced, making it liable to break in handling.

Although the density of the molded mass will differ depending on the amount of binder contained and on the amount of sintering promoter added, preferably it is 1.5 g/cm³ or more. Densities less than 1.5 g/cm³ would mean a relatively large distance between particles in the raw-material powder, which would hinder the progress of the sintering. At the same time, the molded mass density preferably is 2.5 g/cm³ or less. Densities of more than 2.5 g/cm³ would make it difficult to eliminate sufficiently the binder from within the molded mass in a degreasing process of a subsequent step. It would consequently prove difficult to produce an ultrafine sinter as described earlier.

Next, heating and degreasing processes are carried out on the molded mass within a non-oxidizing atmosphere. Carrying out the degreasing process under an oxidizing atmosphere such as air would degrade the thermal conductivity of the sinter, because the AlN powder would become superficially oxidized. Preferable non-oxidizing ambient gases are nitrogen and argon. The heating temperature in the degreasing process is preferably 500Â° C. or more and 1000Â° C. or less. With temperatures of less than 500Â° C., surplus carbon is left remaining within the laminate following the degreasing process because the binder cannot sufficiently be eliminated, which interferes with sintering in the subsequent sintering step. On the other hand at temperatures of more than 1000Â° C., the ability to eliminate oxygen from the oxidized coating superficially present on the surface of the AlN powder deteriorates, such that the amount of carbon left remaining is too little, degrading the thermal conductivity of the sinter.

The amount of carbon left remaining within the molded mass after the degreasing process is preferably 1.0 wt. % or less. If carbon in excess of 1.0 wt. % remains, it will interfere with the sintering, which would mean that ultrafine sinters could not be produced.

Next, sintering is carried out. The sintering is carried out within a non-oxidizing nitrogen, argon, or like atmosphere, at a temperature of 1700 to 2000 Â° C. Therein the moisture contained in the ambient gas such as nitrogen that is employed is preferably â [symbol] 30Â° C. or less given in dew point. If it were to contain more moisture than this, the thermal conductivity of the sinter would likely be degraded, because the AlN would react with the moisture within the ambient gas during sintering and form nitrides. Another preferable condition is that the volume of oxygen within the ambient gas be 0.001 vol. % or less. A larger volume of oxygen would lead to a likelihood that the AlN would oxidize, impairing the sinter thermal conductivity.

As another condition during sintering, the jig employed is suitably a boron nitride (BN) molded part. Inasmuch as the jig as a BN molded part will be sufficiently heat resistant against the sintering temperatures, and superficially will have solid lubricity, when the laminate contracts during sintering, friction between the jig and the laminate will be lessened, which will enable sinters to be produced with little distortion.

The obtained sinter is subjected to processing according to requirements. In cases where a conductive paste is to be screen-printed onto the sinter in a succeeding step, the surface roughness is preferably 5 \hat{l}¼ m or less in Ra. If over 5 \hat{l}¼ m, in screen printing to form circuits, defects such as blotting or pinholes in the pattern are liable to arise. More suitable is a surface roughness of 1 \hat{l}¼ m or less in Ra.

In polishing to the abovementioned surface roughness, although cases in which both sides of the sinter are screen printed are a matter of course, even in cases where screen printing is effected on one side only the polishing process is best carried out on the face on the side opposite the screen-printing face. This is because polishing only the screen-printing face would mean that during screen printing, the sinter would be supported on the unpolished face, and in that situation burrs and debris would be present on the unpolished face, destabilizing the fixedness of the sinter such that the circuit pattern by the screen printing might not be drawn well.

Furthermore, at this point the thickness uniformity (parallelism) between the processed faces is preferably 0.5 mm or less; Thickness uniformity exceeding 0.5 mm can lead to large fluctuations in the thickness of the conductive paste during screen printing. Particularly suitable is a thickness uniformity of 0.1 mm or less. Another preferable condition is that the planarity of the screen-printing face be 0.5 mm or less. If the planarity exceeds 0.5 mm, in that case too there can be large fluctuations in the thickness of the conductive paste during screen printing. Particularly suitable is a planarity of 0.1 mm or less.

Screen printing is used to spread a conductive paste and form the electrical circuits onto a sinter having undergone the polishing process. The conductive paste can be obtained by mixing together with a metal powder an oxidized powder, a binder, and a solvent according to requirements. The metal powder is preferably tungsten, molybdenum or tantalum, since their thermal expansion coefficients match those of ceramics.

Adding the oxidized powder to the conductive paste is also to enhance the strength with which it bonds to AlN. The oxidized powder preferably is an oxide of Group ha or Group IIIa elements, or is Al₂O₃, SiO₂, or a like oxide. Yttrium oxide is especially preferable because it has very good wettability with AlN. The amount of such oxides added is preferably 0.1 to 30 wt. %. If the amount is less than 0.1 wt. %, the bonding strength between AlN and the metal layer being the circuit that has been formed deteriorates. On the other hand, amounts in excess of 30 wt. % make the electrical resistance of the circuit metal layer high.

The thickness of the conductive paste is preferably 5 \hat{l}¼ m or more and 100 \hat{l}¼ m or less in terms of it post-drying thickness. If the thickness were less than 5 \hat{l}¼ m the electrical resistance would be too high and the bonding strength decline. Likewise, if in excess of 100 \hat{l}¼ m the bonding strength would deteriorate in that case too.

Also preferable is that in the patterns for the circuits that are formed, in the case of the heater circuit (resistive heating element circuit), the pattern spacing be 0.1 mm or more. With a spacing of less than 0.1 mm, shorting will occur when current flows in the resistive heating element and, depending on the applied voltage and the temperature, leakage current is generated. Particularly in cases where the circuit is employed at temperatures of 500Â° C. or more, the pattern spacing preferably should be 1 mm or more; more preferable still is that it be 3 mm or more.

After the conductive paste is degreased, baking follows. Degreasing is carried out within a non-oxidizing nitrogen, argon, or like atmosphere. The degreasing temperature is preferably 500Â° C. or more. At less than 500Â° C., elimination of the binder from the conductive paste is inadequate, leaving behind carbon in the metal layer that during baking will form carbides with the metal and consequently raise the electrical resistance of the metal layer.

The baking is suitably done within a non-oxidizing nitrogen, argon, or like atmosphere at a temperature of 1500Â° C. or more. At temperatures of less than 1500Â° C., the post-baking electrical resistance of the metal layer turns out too high because the baking of the metal powder within the paste does not proceed to the grain growth stage. A further baking parameter is that the baking temperature should not surpass the firing temperature of the ceramic produced. If the conductive paste is baked at a temperature beyond the firing temperature of the ceramic, dispersive volatilization of the sintering promoter incorporated within the ceramic sets in, and moreover, grain growth in the metal powder within the conductive paste is accelerated, impairing the bonding strength between the ceramic and the metal layer.

In order to ensure that the metal layer is electrically isolated, an insulative coating can be formed on the metal layer. Preferably the insulative coating substance is the same substance as the ceramic on which the metal layer is formed. Problems such as post-sintering warpage arising from the difference in thermal expansion coefficient will occur if the ceramic and insulative coating substances differ significantly. For example, in a case where the ceramic is AlN, a predetermined amount of an oxide/carbide of a Group IIa element or a Group IIIa element can be added to and mixed together with AlN powder, a binder and a solvent added and the mixture rendered into a paste, and the paste can be screen-printed to spread it onto the metal layer.

In that case, the amount of sintering promoter added preferably is 0.01 wt. % or more. With an amount less than 0.01 wt. % the insulative coating does not densify, making it difficult to secure electrical isolation of the metal layer. It is further preferable that the amount of sintering promoter not exceed 20 wt. %. Surpassing 30 wt. % leads to excess sintering promoter invading the metal layer, which can end up altering the metal-layer electrical resistance. Although not particularly limited, the spreading thickness preferably is 5 \hat{l}¼ m or more. This is because securing electrical isolation proves to be problematic at less than 5 \hat{l}¼ m.

Further according to the present method, the ceramic as substrates can be laminated according to requirements. Lamination may be done via a bonding agent. The bonding agent—being is a compound of Group IIa or Group IIIa elements, and a binder and solvent, added to an aluminum oxide powder or aluminum nitride powder and made into a paste—is spread onto the bonding surface by a technique such as screen printing. The thickness of the applied bonding agent is not particularly restricted, but preferably is 5 \hat{l}¼ m or more. Bonding defects such as pinholes and bonding irregularities are liable to arise in the bonding layer with thicknesses of less than 5 \hat{l}¼ m.

The ceramic substrates onto which the bonding agent has been spread are degreased within a non-oxidizing atmosphere at a temperature of 500Â° C. or more. The ceramic substrates are thereafter bonded to one another by stacking the ceramic substrates together, applying a predetermined load to the stack, and heating it within a non-oxidizing atmosphere. The load preferably is 0.05 kg/cm² or more. With loads of less than 0.05 kg/cm² sufficient bonding strength will not be obtained, and otherwise defects in the bond will likely occur.

Although the heating temperature for bonding is not particularly restricted as long as it is a temperature at which the ceramic substrates adequately bond to one another via the bonding layers, preferably it is 1500Â° C. or more. At less than 1500Â° C. adequate bonding strength proves difficult to gain, such that defects in the bond are liable to arise. Nitrogen or argon is preferably employed for the non-oxidizing atmosphere during the degreasing and boding just discussed.

A ceramic sinter laminate that serves as a wafer holder thus can be produced as in the foregoing. As far as the electrical circuits are concerned, it should be understood that if they are heater circuits for example, then a molybdenum coil can be utilized, and in the electrostatic-chuck electrode and RF electrode cases, molybdenum or tungsten mesh can be, without employing conductive paste.

In this case, the molybdenum coil or the mesh can be built into the AlN raw-material powder, and the wafer holder can be fabricated by hot pressing. While the temperature and atmosphere in the hot press may be on par with the AlN sintering temperature and atmosphere, the hot press desirably applies a pressure of 10 kg/cm² or more. With pressure of less than 10 kg/cm², the wafer holder might not exhibit its capabilities, because gaps arise between the AlN and the molybdenum coil or the mesh.

Co-firing will now be described. The earlier-described raw-material slurry is molded into a sheet by doctor blading. The sheet-molding parameters are not particularly limited, but the post-drying thickness of the sheet advisably is 3 mm or less. The sheet thickness surpassing 3 mm leads to large shrinkage in the drying slurry, raising the probability that fissures will be generated in the sheet.

A metal layer of predetermined form that serves as an electrical circuit is formed onto the abovementioned sheet using a technique such as screen printing to spread onto it a conductive paste. The conductive paste utilized can be the same as that which was descried under the post-metallization method. Nevertheless, not adding an oxidized powder to the conductive paste does not hinder the co-firing method.

Subsequently, sheets that have undergone circuit formation are laminated with sheets that have not. Lamination is by setting the sheets each into position to stack them together. Therein, according to requirements, a solvent is spread on between sheets. In the stacked state, the sheets are heated as may be necessary. In cases where the stack is heated, the heating temperature is preferably 150Â° C. or less. Heating to temperatures in excess of this greatly deforms the laminated sheets. Pressure is then applied to the stacked-together sheets to unitize them. The applied pressure is preferably within a range of from 1 to 100 MPa. At pressures less than 1 MPa, the sheets are not adequately unitized and can peel apart during subsequent processes.

Likewise, if pressure in excess of 100 MPa is applied, the extent to which the sheets deform becomes too great.

This laminate undergoes a degreasing process as well as sintering, in the same way was with the post-metallization method described earlier. Parameters such as the temperature in degreasing and sintering and the amount of carbon are the same as with post-metallization. In the previously described screen printing of a conductive paste onto sheets, a wafer holder having a plurality of electrical circuits can be readily fabricated by printing heater circuits, electrostatic-chuck electrodes, etc. respectively onto a plurality of sheets and laminating them. In this way a ceramic laminated sinter that serves as a wafer holder can be produced.

The obtained ceramic laminated sinter is subject to processing according to requirements. Routinely with semiconductor manufacturing devices, in the sintered state the ceramic laminated sinter often cannot be gotten into the precision demanded. The planarity of the wafer-carrying face as an example of processing precision is preferably 0.5 mm or less; moreover 0.1 mm or less is particularly preferable. The planarity surpassing 0.5 mm is apt to give rise to gaps between the wafer and the wafer holder, keeping the heat of the wafer holder from being uniformly transmitted to the wafer and making likely the generation of temperature irregularities in the wafer.

A further preferable condition is that the surface roughness of the wafer-carrying face be 5 \hat{l}¼ m in Ra. If the roughness is over 5 \hat{l}¼ m in Ra, grains loosened from the AlN due to friction between the wafer holder and the wafer can grow numerous. Particles loosened in that case become contaminants that have a negative effect on processes, such as film deposition and etching, on the wafer. Furthermore, then, a surface roughness of 1 \hat{l}¼ m or less in Ra is ideal.

A wafer holder base part can thus be fabricated as in the foregoing. A shaft may be attached to the wafer holder as needed. Although the shaft substance is not particularly limited as long as its thermal expansion coefficient is not appreciably different from that of the wafer-holder ceramic, the difference in thermal expansion coefficient between the shaft substance and the wafer holder preferably is 5 Â□10^{Â|-6} K or less.

If the difference in thermal expansion coefficient exceeds 5 Â□10^{Â|-6} K, cracks can arise adjacent the joint between the wafer holder and the shaft when it is being attached; but even if cracks do not arise when the two are joined, splitting and cracking can occur in the joint in that it is put through heating cycling in the course of being repeatedly used. For cases in which the wafer holder is AlN, for example, the shaft substance is optimally AlN; but silicon nitride, silicon carbide, or mullite can be used.

Mounting is joining via an adhesive layer. The adhesive layer constituents preferably are composed of AlN and Al₂O₃, as well as rare-earth oxides. These constituents are preferable because of their favorable wettability with ceramics such as the AlN that is the substance of the wafer holder and the shaft, which makes the joint strength relatively high, and readily produces a gastight joint surface.

The planarity of the respective joining faces of the shaft and wafer holder to be joined preferably is 0.5 mm or less. Planarity greater than this makes gaps liable to occur in the joining faces, impeding the production of a joint having adequate gastightness. A planarity of 0.1 mm or less is more suitable. Here, still more suitable is a planarity of the wafer holder joining faces of 0.02 mm or less. Likewise, the surface of the respective joining faces preferably is 5 \hat{l}¼ m or less in Ra. Surface roughness exceeding this would then also mean that gaps are liable to occur in the joining faces. A surface roughness of 1 \hat{l}¼ m or less in Ra is still more suitable.

Subsequently, electrodes are attached to the wafer holder. The attaching can be done according to publicly known techniques. For example, the side of the wafer holder opposite its wafer-carrying surface may be spot faced through to the electrical circuits, and metallization carried out on the circuit, or without metallizing, electrodes of molybdenum, tungsten, etc. may be connected to it directly using activated metal solder. The electrodes can thereafter be plated as needed to improve their resistance to oxidation. In this way, a wafer holder for semiconductor manufacturing devices can be fabricated.

Moreover, semiconductor wafers can be processed on a wafer holder according to the present invention, integrated into a semiconductor manufacturing device. Inasmuch as the temperature of the wafer-carrying surface of a wafer holder by the present invention is uniform, the temperature distribution in the wafer will be more uniform than is conventional, to yield stabilized characteristics in terms of deposited films, heating processes, etc.

### EMBODIMENTS

### Embodiment 1

99 parts by weight aluminum nitride powder and 1 part by weight Y₂O₃ powder were mixed and blended with 10 parts by weight polyvinyl butyral as a binder and 5 parts by weight dibutyl phthalate as a solvent, and doctor-bladed into a green sheet 430 mm in diameter and 1.0 mm in thickness. Here, an aluminum nitride powder having a mean particle diameter of 0.6 \hat{l}¼ m and a specific surface area of 3.4 m²/g was utilized. In addition, a tungsten paste was prepared utilizing 100 parts by weight of a tungsten powder whose mean particle diameter was 2.0 \hat{l}¼ m; and per that, 1 part by weight Y₂O₃ and 5 parts by weight ethyl cellulose, being a binder; and butyl Carbitolâ□c as a solvent. A pot mill and a triple-roller mill were used for mixing. This tungsten paste was formed into a heater circuit pattern by screen-printing onto the green sheet.

Pluralities of separate green sheets of thickness 1.0 mm were laminated onto the green sheet printed with the heater circuit to create laminates whose total thickness was in three thickness categories. Lamination was carried out by stacking the sheets in place in a mold, and thermopressing 2 minutes in a press at a pressure of 10 MPa while maintaining 50Â° C. heat. The laminates were thereafter degreased within a nitrogen atmosphere at 600Â° C., and sintered within a nitrogen atmosphere under time and temperature conditions of 3 hours and 1800Â° C., whereby wafer holders were produced. Here, a polishing process was performed on the wafer-carrying surface so that it would be 1 \hat{l}¼ m or less in Ra, and on the shaft-joining face so that it would be 5 \hat{l}¼ m or less in Ra. The wafer holders were also processed to true their outer diameter. The dimensions of post-processing wafer holders were 340 mm outer diameter and 16 mm thickness.

A shaft made of AlN, 80 mm outside diameter, 60 mm inside diameter, and 300 mm length was attached to the surface of each wafer holder on the side opposite the wafer-carrying surface. The adhesive agent was 50% Al₂O₃â□□30% Y₂O₃â□□20% AlN. The fact that the outer diameter of the shafts was 80 mm and the thickness of the wafer holders was 16 mm meant that the heat capacity of the region of the wafer holders corresponding to the shafts was 53.88 J/gK.

The heater circuits in the wafer holders were partially exposed by spot-facing through the surface on the side opposite the wafer-carrying surface, up to the heater circuit. Electrodes made of molybdenum were connected directly to the exposed portions of the heater circuits utilizing an active metal brazing material. The wafer holders were heated by passing current through the electrodes, and their isothermal ratings were measured. Here, the diameter of the electrodes was made 4 mm, and the length, 300 mm. Also, electrodes in the numbers set forth in Table I were attached in each case.

Measurement of isothermal ratings was by setting a 12-inch wafer temperature gauge on the wafer-carrying surfaces and measuring their temperature distributions. It should be understood that the power supply was adjusted so that the temperature in the midportion of the wafer temperature gauge would be 550Â° C. The results are set forth in Table I. Here, shown in Table I are the gross heat capacity of the electrodes is tabulated as the electrode heat capacity, and its proportion relative to the heat capacity of the wafer holder section corresponding to the shaft is tabulated as the heat capacity percentage.

TABLE I

| | Number of | Electrode heat | Heat capacity | Isothermal |
|---|---|---|---|---|
| No. | electrodes | capacity (J/gK) | percentage (%) | rating (%) |
| 1 | 2 | 1.01 | 1.8 | Â ± 0.36 |
| 2 | 4 | 2.02 | 3.7 | Â ± 0.43 |
| 3 | 6 | 3.03 | 5.6 | Â ± 0.51 |
| 4 | 8 | 4.04 | 7.5 | Â ± 0.74 |
| 5 | 10 | 5.05 | 9.3 | Â ± 0.85 |

### Embodiment 2

Wafer holders made of AlN, 340 mm outside diameter, and 19 mm thickness were prepared likewise as with Embodiment 1. A shaft made of AlN like in Embodiment 1 was attached to each wafer holder in the same manner as in Embodiment 1. Because the wafer holders were made 19 mm in thickness, the heat capacity of the region of the wafer holders corresponding to the shaft was 63.98 J/gK. In addition, electrodes in the numbers set forth in Table II were attached likewise with Embodiment 1, and the temperature distribution at 550Â° C. was measured in the same way as in Embodiment 1. The results are given in Table II.

TABLE II

| | Number of | Electrode heat | Heat capacity | Isothermal |
|---|---|---|---|---|
| No. | electrodes | capacity (J/gK) | percentage (%) | rating (%) |
| 6 | 2 | 1.01 | 1.5 | Â ± 0.35 |
| 7 | 4 | 2.02 | 3.1 | Â ± 0.39 |
| 8 | 6 | 3.03 | 4.7 | Â ± 0.48 |
| 9 | 8 | 4.04 | 6.3 | Â ± 0.68 |
| 10 | 10 | 5.05 | 7.8 | Â ± 0.75 |

### Embodiment 3

Wafer holders made of AlN, 340 mm outside diameter, and 19 mm thickness were prepared likewise as with Embodiment 1. A shaft made of AlN like in Embodiment 1 was attached to each wafer holder in the same manner as in Embodiment 1. In addition, electrodes in the outer diameters and numbers set forth in Table III were attached likewise as Embodiment 1, and the temperature distribution at 550Â° C. was measured in the same way as in Embodiment 1. The results are given in Table III.

TABLE III

| | Electrode | | Electrode | Heat | |
|---|---|---|---|---|---|
| | outer | | heat | capacity | |
| | diameter | Number of | capacity | percentage | Isothermal |
| No. | (mm) | electrodes | (J/gK) | (%) | rating (%) |
| 11 | 8 | 2 | 4.04 | 6.3 | Â ± 0.62 |
| 12 | 8 | 4 | 8.08 | 12.6 | Â ± 1.26 |
| 13 | 8 | 6 | 12.12 | 18.9 | Â ± 2.92 |
| 14 | 12 | 2 | 9.09 | 14.2 | Â ± 1.69 |
| 15 | 12 | 4 | 18.18 | 28.4 | Â ± 3.88 |
| 16 | 12 | 6 | 27.27 | 42.6 | Â ± 5.35 |

As is evident from Tables I through III, by making the in-shaft heat capacity of the electrodes 10% or less of the heat capacity of the region of the wafer holder that corresponds to the shaft, the temperature distribution in the wafer surface can be brought within an isothermal rating of Â±1.0%. What is more, if the heat capacity of the electrodes is made to be 5% or less of the heat capacity of the region of the wafer holder that corresponds to the shaft, the temperature distribution in the wafer surface can be brought within an isothermal rating of Â±0.5%.

### Embodiment 3

The wafer holders of Tables I through II were assembled into a semiconductor manufacturing device, wherein TiN films were formed onto silicon wafers 12 inches in diameter. In cases in which wafer holders Nos. 12 through 16 were used, fluctuations in the TiN film thickness were a large 15% or more; but being that in cases in which the wafer holders other than these were utilized, fluctuations in the film thickness were a small 10% or less, excellent TiN films could be formed.

According to the present invention as given in the foregoing, making the in-shaft heat capacity of the electrodes 10% or less of the heat capacity of the wafer holder region that corresponds to the shaft enables providing wafer holders and semiconductor manufacturing devices of superior isothermal rating.

What is claimed is:

1. A wafer holder for semiconductor manufacturing devices, the wafer holder having a wafer-carrying surface and comprising:
a shaft joined to the wafer holder for supporting the wafer holder;
an electrical circuit formed either on a surface other than the wafer-carrying surface of the wafer holder, or else inside it; and
electrodes within said shaft, for supplying power to said electrical circuit, the heat capacity of said electrodes where they are within said shaft being 10% or less of the heat capacity of a region of the wafer holder that corresponds to inside the outer periphery of said shaft.

2. The wafer holder set forth in claim 1, wherein the electrical circuit formed in the wafer holder is at least a resistive heating element.

3. A semiconductor manufacturing device wherein the wafer holder set forth in claim 1 is installed.

4. A semiconductor manufacturing device wherein the wafer holder set forth in claim 2 is installed.
